(19) United States
(12) Patent Application Publication
(10) Pub. No.: US 2023/0031577 A1
(43) Pub. Date: Feb. 2, 2023

(54) METHOD AND SYSTEMS FOR FABRICATING SUPERCONDUCTING NANOWIRE SINGLE PHOTON DETECTOR (SNSPD)

(71) Applicant: SUPERQ TECHNOLOGIES INDIA PVT LTD, BANGALORE (IN)

(72) Inventors: MANJUNATH GANGAIAH, RAMNAGRAM (IN); AMLAN MUKHERJEE, DURGAPUR (IN); NAGENDRA NAGARAJA, BANGALORE (IN); PINAKIN MANSUKHLAL PADALIA, RAJKOT (IN); BALAJI SOMPALLE, BANGALORE (IN); PURNIMA SETHI JOSAN, BANGALORE (IN); SUBHASH KANNAPPA MANOHARAN, BANGALORE (IN)

(21) Appl. No.: 17/861,166

(22) Filed: Jul. 8, 2022

(30) Foreign Application Priority Data
Jul. 8, 2021 (IN) 202141030763

(51) Int. Cl. H01L 39/24; G01J 1/44

(52) U.S. Cl. CPC H01L 39/249; G01J 1/44; G01J 2001/442

(57) ABSTRACT

A method and a system for fabricating superconducting nanowire single photon detector (SNSPD) is disclosed. The superconducting nanowire single photon detector consists of a thin film of superconducting material shaped into a meandering nanowire through nanofabrication processes. The pattern enables the nanowire to cover a wide surface area. The SNSPD is a type of near-infrared single-photon detector based on a current-biased superconducting nanowire. The method includes depositing a plurality of buffer layers on a substrate of a superconducting nanowire single photon detector using a pulsed laser deposition technique. The method further includes designing deposited buffer layer into a desired pattern of nanostrips and depositing a plurality of high temperature superconductor (HTS) on the desired pattern of nanostrips. To obtain the desired pattern, at least one of lithography and/or etching processes is used in the SNSPD.

### CROSS-REFERENCE TO RELATED APPLICATIONS

The embodiments herein claim the priority of the Indian Provisional Patent Application numbered IN 202141030763 filed on Jul. 8, 2021, with the title “A METHOD AND SYSTEM FOR FABRICATING SUPERCONDUCTING NANOWIRE SINGLE PHOTON DETECTOR”, and the contents of which are included entirely as reference herein.

### BACKGROUND

### Technical Field

The present invention is generally related to the field of superconducting devices. The present invention is particularly related to High Temperature Superconducting devices such as a superconducting single photon detector operated at high temperatures. The present invention is more particularly related to a method of fabricating Superconducting Nanowire Single Photon Detectors (SNSPDs). The present invention is further related to a method for fabrication of High temperature Superconducting (HTS) materials for the fabrication of superconducting nanowires. The present invention is still further related to the methods of the fabrication of the HTS nanowires on a well patterned substrates to yield high quality nanowire detector structures suitable for detecting single photons.

### Description of the Related Art

Typically, a photon detector counts photons of light. A photon detector has a surface that absorbs photons and produces an effect (such as current and/or voltage) proportional to the number of photons that are absorbed. The photons are the quanta of light. The energy of each photon is related to its frequency, ν (or alternatively the wavelength λ). The equation that connects energy of the photon to the respective frequency is E=hv (or he/λ). To elaborate, h is the Planck's constant (=6.62607004×10⁻³⁴ m² kg/s), ν is the frequency of light, c is the speed of light (=299,792,458 m/s) and λ refers to the wavelength of light. Notably, the detection of photons find application in various fields, such as communication and metrology, time-correlated photon counting, fluorescence measurement, singlemolecule detection, environment analyses, laser rangefinders, quantum cryptography and others. The conventional way to detect a single particle of light (or the photon) is to catch it with a sensor, absorbing its energy and destroying the particle in the process. In other words, to detect a single photon, a single photon detector is used. The single photon detector provides an electrical signal as an output upon detection of a single photon of incident light. Various implementations of the single photon detector are possible.

The performance of the single photon detector is decided by the important parameters such as a system detection efficiency, a dark count rate, a jitter timing, a counting rate, and the like. The system detection efficiency is defined as the probability that output signal is generated after the absorption of incident photons. Additionally, electrical noise and stray light may behave as an optical signal and generate the voltage signal. The event of generation of the voltage signal may be referred as a false detection event. Moreover, the false detection event is also called as a dark count, and the number of dark counts in a unit time is specified by the dark count rate. Furthermore, the time between the incidence of the photon at the single photon detector and generation of output signal by the single photon detectors is known as jitter timing. Typically, the single photon detectors have a high system detection efficiency, low dark count rate, very short jitter timing.

Currently, semiconducting single photon detectors (SPAD) such as the single-photon avalanche diodes are in use. The SPADs are made from different materials such as Silicon, In GaAs/InP etc. The SPADs are being used for various applications and commercial purposes. Commercially available SPADs have been employed to detect the photons which exhibit system detection efficiency of about less than 40%. Further SPADs possess a high dark count which is nearly several tens of thousands of counts per second, and a low counting rate. However, the current conventional detectors are not efficient when high system detection efficiency is desired for an application. Moreover, they are also not efficient for cases that require a very low dark count and a high counting rate.

Further, the introduction of Superconducting nanowire single photon detectors (SNSPD) has successfully gained the potential to detect single photons with desired characteristics such as high system detection efficiency of more than 90%, small number of dark counts and high counting rate as compared to SPADs. Also, SNSPDs are indispensable for a variety of applications including free-space and satellite communications, quantum cryptography, quantum communications, semiconductor device testing, etc. Currently, polycrystalline NbN based superconducting nanowire single photon detectors exhibit the system detection efficiency of more than 90% for 1550 nm wavelength photons at an operating temperature of 2.1 K and the efficiency is increased to 92% when the operating temperature is lowered to 1.8 K. Specifically, amorphous tungsten silicide based SNSPDs are capable of detecting the photons of wavelength near to infra-red light with system detection efficiency of more than 93%, and low dark count rate of less than 1 cps at operating temperature 0.12 K. Further, SNSPDs other than amorphous tungsten silicide based SNSPDs have been developed to perform the detection of the single photons with moderate efficiency at very lower operating temperatures.

The present SNSPDs perform the function at very low temperature, nearly less than the liquid helium temperature (<4.2 K). This summonses the setting up of the high cooling system, this costs not only high initial investment but also results in high maintenance costs. The operation temperature of the SNSPDs is mainly decided by the two factors, selection of the functional materials having high transition temperature (Tc) and the way of fabricating the array of nanowires as this ultimately affects the superconducting properties of the material. The steps involved in the fabrication of nanowire/nanostrips of the SNSPDs are deposition of the superconducting thin films on the substrate. Further, the fabrication is followed by etching to obtain the required nanopattern. Numerous methods are in existence for etching techniques that are employed to fabricate the nanowires/nanostrip but deteriorates the properties of the superconducting material. For instance, the plasma etching was employed to fabricate the nanostrip from the sputtered NbN film on R-plane sapphire substrates. It is found that the resistance of the materials increased and the (Tc) of the obtained nanostrips is decreased. It is concluded that post processing of the deposited superconducting thin films deteriorates the indispensable properties and cause not only a decrease in the system efficiency but also a decrease in temperature at which the detection of photons is performed.

Hence there is need for a method and a system for fabrication of Superconducting Nanowire Single Photon Detectors (SNSPDs) by making use of High Temperature Superconductors without reduction in detection efficiency and operating temperatures. Further there is a need for a fabrication method of Superconducting Nanowire Single Photon Detectors (SNSPDs) by making use of High Temperature Superconductors integrated with electronics to obtain a system capable of operating at temperatures higher than 4 K thereby maintaining a quality of the superconducting material. Still further there is a need for a fabrication process for developing of a cost-effective single photon detector by depositing high-quality films.

The above-mentioned shortcomings, disadvantages and problems are addressed herein, and which will be understood by reading and studying the following specification.

### OBJECTS OF THE INVENTION

The primary object of the present invention is to provide a method and a system of fabricating of nanowires without post processing the superconducting thin films.

Another object of the present invention is to provide a system and method of selecting the superconductor materials and an efficient fabrication of the nanowires for manufacturing Superconducting nanowire single photon detectors (SNSPD).

Yet another object of the present invention is to a system and method of fabricating Superconducting nanowire single photon detectors (SNSPD) using high temperature superconductors with Tc higher than the liquid nitrogen temperature.

Yet another object of the invention is to provide a system and method for fabricating an array of nanowires on the silicon substrates using pulsed laser deposition (PLD) technique for manufacturing Superconducting nanowire single photon detectors (SNSPD).

Yet another object of the present invention is to provide a method and a system for an efficient fabrication of nanowires for fabricating photon detectors with higher operating temperatures and higher detection efficiency.

Yet another object of the present invention is to provide a method and a systern for fabricating Superconducting nanowire single photon detectors (SNSPD) using high temperature superconductors with Tc higher than 77K.

Yet another object of the present invention is to provide a method and a system for fabricating high temperature superconductors by eliminating a need for deposition and wiping out of the Gold (Au) encapsulation layer or passivation layer before and after the formation of nanostrips, thereby reducing the time of fabricating process and developing a cost-effective fabricating process for an industrial setting.

Yet another object of the present invention is to provide a method and a system for fabricating, high temperature superconductors without deterioration in the properties of the superconducting materials.

These and other objects and advantages will become more apparent when reference is made to the following description and accompanying drawings.

### SUMMARY

The following details present a simplified summary of the embodiments herein to provide a basic understanding of the several aspects of the embodiments herein. This summary is not an extensive overview of the embodiments herein. It is not intended to identify key/critical elements of the embodiments herein or to delineate the scope of the embodiments herein. Its sole purpose is to present the concepts of the embodiments herein in a simplified form as a prelude to the more detailed description that is presented later.

The other objects and advantages of the embodiments herein will become readily apparent from the following description taken in conjunction with the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

In one aspect a method of fabricating superconducting nanowire single photon detector (SNSPD) is provided. The method includes depositing a plurality of buffer layers on a substrate of a superconducting nanowire single photon detector using a pulsed laser deposition technique. The method further includes designing deposited buffer layer into a desired pattern of nanostrips and depositing a plurality of high temperature superconductor (HTS) on the desired pattern of nanostrips.

In an embodiment, a lattice matching with the buffer layer and the lattice mismatching with the substrate allows the deposition of continuous and high quality superconducting thin film on the desired pattern.

In an embodiment, the pulsed laser deposition technique is a physical vapor deposition (PVD) technique. The pulsed laser deposition technique includes focusing a high-power pulsed laser beam inside a vacuum chamber to strike the plurality of buffer layers. The technique further includes vaporizing the material of the plurality of buffer layers in a plasma plume and depositing the material as a thin film on the substrate of superconducting nanowire single photon detector.

In an embodiment, at least one of lithography or etching processes is used in the SNSPD to obtain the desired pattern.

In an embodiment, the lithography process includes depositing a plurality of buffer layer on top of the silicon substrate. The process further includes performing a post-deposition lithography on the buffer layer using an electron beam at 20-100 Kilo Volts (KV) for providing high resolution. The process further includes scanning the image according to a pattern defined on a computer aided design (CAD) file using the electron beam and developing the sample in an appropriate solvent for revealing the structures defined into the resist.

In an embodiment, the etching process includes generating the plasma under low pressure by electromagnetic field. The process further includes attacking the wafer surface using high energy ions from the plasma and removing materials deposited on the substrate using a plasma.

In an embodiment, a superconducting material film is uniformly and non-conformally deposited on the desired pattern.

In another aspect a method of working of a single photon detector (SNSPD) is provided. The method includes patterning the superconducting nanowire in a compact meander geometry to create a shape. The method further includes cooling the superconducting nanowire, below a superconducting critical temperature and biasing with a direct current close to and less than the superconducting critical current of the nanowire. The method further includes collecting the whole output of an optical fiber using the superconducting nanowire. The method further includes operating the SNSPD at a certain temperature. The method further includes applying a constant current below the critical current of the superconductor to the device. The method further includes giving the SNSPD a high level of sensitivity upon absorption of just a single photon using the nanoscale crosssection. The method further includes absorbing a single photon in the meandering nanowire. The superconductivity is locally broken. The method further includes directing the current towards the amplification electronics. The method further includes creating a voltage pulse and recovering the superconductivity in the nanowire within a short time after the photon is absorbed.

In an embodiment, the method further includes repeating the steps for a plurality of photons, with one photon at a time.

In an embodiment, creating the voltage pulse includes incidenting a photon on the nanowire. The method further includes breaking a plurality of Cooper pairs in the nanowires using the plurality of photons. The method further includes absorbing the photon in the nanowire. The method further includes resulting in the formation of a localized non-superconducting region or hotspot, with finite electrical resistance. The method further incausing a spike in the resistance of superconducting nanowire from zero to a finite value causes the voltage pulse to be generated across the nanowire by exceeding the local current density from the critical current density. The method further includes recovering superconductivity in the nanowire within a short time and preparing the nanowire to absorb next incident photon.

In an embodiment, a resistive barrier is formed across the width of the superconductor nanowire.

In an embodiment, the resistive barrier will lead to the production of the measurable voltage pulse.

In an embodiment, the optical fiber is associated with data transmission using light pulses travelling along with a long fiber which is usually made of plastic or glass.

In an embodiment, the metal wires are used for transmission in optical fiber communication as signals travel with fewer damages while constituting a single path for the current.

In another aspect a superconducting nanowire single photon detector (SNSPD) is provided. The SNSPD includes a thin film of superconducting material shaped into a meandering nanowire through nanofabrication processes. The pattern enables the nanowire to cover a wide surface area.

In an embodiment, the SNSPD is a type of near-infrared single-photon detector based on a current-biased superconducting nanowire.

In an embodiment, the length of the superconducting nanowire is typically hundreds of micrometers.

In an embodiment, the nanowire is patterned in a compact meander geometry to create a shape.

In an embodiment, the nanowire is cooled well below the superconducting critical temperature and biased with a DC current that is close to but less than the superconducting critical current of the nanowire.

In an embodiment, the SNSPD is operated at a certain temperature and a constant current below the critical current of the superconductor is applied to the device.

In an embodiment, the nanoscale cross section gives the SNSPD an extremely high level of sensitivity upon absorption of a single photon.

The embodiments of the present invention provide a method and a system for fabricating superconducting nanowire single photon detector. The described fabrication method preserves the quality of the superconducting material and thereby solve multiple problems related to the fabrication process. The fabrication process allows a high-quality film to be deposited and allows development of a cost-effective single photon detector. The fabrication of SNSPD using the described method can be used for various different substrates, buffer layers and HTS materials and hence provides a flexible solution. Moreover, the fabrication is applicable to other such processes involving superconducting materials. Also, the described method eliminates the step of gold encapsulation and currently gold encapsulation results in deterioration of the superconducting properties in the fabrication. Such deterioration of the superconducting properties can be eliminated completely and hence the fabrication process is made much simpler.

The foregoing description of the specific embodiments will so fully reveal the general nature of the embodiments herein that others can, by applying current knowledge, readily modify and/or adapt for various applications such as specific embodiments without departing from the generic concept, and, therefore, such adaptations and modifications should and are intended to be comprehended within the meaning and range of equivalents of the disclosed embodiments.

It is to be understood that the phraseology or terminology employed herein is for the purpose of description and not of limitation. Therefore, while the embodiments herein have been described in terms of preferred embodiments, those skilled in the art will recognize that the embodiments herein can be practiced with modifications. However, all such modifications are deemed to be within the scope of the claims.

### BRIEF DESCRIPTION OF THE DRAWINGS

The other objects, features and advantages will occur to those skilled in the art from the following description of the preferred embodiment and the accompanying drawings in which:

FIG. 1A illustrates a Superconducting Nanowire Single Photon Detector (SNSPD) with meandered superconducting nanowire, according to an embodiment of the present invention.

FIG. 1B illustrates a plurality of processes in the fabrication of the Superconducting Nanowire Single Photon Detector (SNSPD) from the deposition of thin films, according to an embodiment of the present invention.

FIG. 2 illustrates a plurality of processes in the fabrication of superconducting nanowire single photon detector from the deposited thin films according to a prior art.

FIG. 3 illustrates a plurality of processes in the fabrication of superconducting nanowires single photon detector from the deposited thin films, according to an embodiment of the present invention.

FIG. 4 illustrates a flow chart explaining a method of fabricating superconducting nanowire single photon detector, according to a prior art.

FIG. 5 illustrates a flow chart explaining a method of fabricating superconducting nanowire single photon detector, in accordance with an embodiment of the present invention.

Although the specific features of the present invention are shown in some drawings and not in others. This is done for convenience only as each feature may be combined with any or all of the other features in accordance with the present invention.

### DETAILED DESCRIPTION OF THE DRAWINGS

The detailed description of various exemplary embodiments of the disclosure is described herein with reference to the accompanying drawings. It should be noted that the embodiments are described herein in such details as to clearly communicate the disclosure. However, the details provided herein is not intended to limit the anticipated variations of embodiments; on the contrary, the intention is to cover all modifications, equivalents, and alternatives falling within the spirit and scope of the present disclosure as defined by the appended claims.

It is also to be understood that various arrangements may be devised that, although not explicitly described or shown herein, embody the principles of the present disclosure. Moreover, all statements herein reciting principles, aspects, and embodiments of the present disclosure, as well as specific examples, are intended to encompass equivalents thereof.

While the disclosure is susceptible to various modifications and alternative forms, specific embodiment thereof has been shown by way of example in the drawings and will be described in detail below. It should be understood however, it is not intended to limit the disclosure to the forms disclosed, but on the contrary, the disclosure is to cover all modifications, equivalents, and alternatives falling within the scope of the disclosure.

According to an embodiment herein, a method of fabricating superconducting nanowire single photon detector (SNSPD) is provided. The method comprising steps of depositing a plurality of buffer layers on a substrate of a superconducting nanowire single photon detector using a pulsed laser deposition technique; designing deposited buffer layer into a desired pattern of nanostrips; and depositing a plurality of high temperature superconductor (HTS) on the desired pattern of nanostrips.

According to an embodiment herein, a lattice matching with the buffer layer and the lattice mismatching with the substrate allows the deposition of continuous and high quality superconducting thin film on the desired pattern.

According to an embodiment herein, the pulsed laser deposition technique is a physical vapor deposition (PVD) technique, and wherein the pulsed laser deposition technique comprises focusing a high-power pulsed laser beam inside a vacuum chamber to strike the plurality of buffer layers; vaporizing the material of the plurality of buffer layers in a plasma plume; and depositing the material as a thin film on the substrate of superconducting nanowire single photon detector.

According to an embodiment herein, at least one of lithography or etching processes is used in the SNSPD to obtain the desired pattern.

According to an embodiment herein, the lithography process comprises depositing a plurality of buffer layer on top of the silicon substrate; performing a post-deposition lithography on the buffer layer using an electron beam at 20 kilo volts (KY) or more for providing high resolution; scanning the image according to a pattern defined on a computer aided design (CAD) file using the electron beam; and developing the sample in an appropriate solvent for revealing the structures defined into the resist.

According to an embodiment herein, the etching process comprises generating the plasma under low pressure by electromagnetic field; attacking the wafer surface using high energy ions from the plasma; and removing materials deposited on the substrate using a plasma.

According to an embodiment herein, a superconducting material film is uniformly and non-conformally deposited on the desired pattern.

According to an embodiment herein, a method of working of a single photon detector (SNSPD) is provided. The method comprising the steps of patterning the superconducting nanowire in a compact meander geometry to create a shape; cooling the superconducting nanowire, below a superconducting critical temperature and biasing with a direct current close to and less than the superconducting critical current of the nanowire; collecting the whole output of an optical fiber using the superconducting nanowire; operating the SNSPD at a certain temperature; applying a constant current below the critical current of the superconductor to the device; giving the SNSPD a high level of sensitivity upon absorption of just a single photon using the nanoscale cross section; absorbing a single photon in the meandering nanowire, wherein the superconductivity is locally broken; directing the current towards the amplification electronics; creating a voltage pulse; and recovering the superconductivity in the nanowire within a short time after the photon is absorbed.

According to an embodiment herein, the method further comprises repeating the steps for a plurality of photons, with one photon at a time.

According to an embodiment herein, the step of creating the voltage pulse comprises making a photon to incident on the nanowire; breaking a plurality of Cooper pairs in the nanowires using the plurality of photons; absorbing the photon in the nanowire; resulting in the formation of a localized non-superconducting region or hotspot, with finite electrical resistance; causing a spike in the resistance of superconducting nanowire from zero to a finite value causes the voltage pulse to be generated across the nanowire by exceeding the local current density from the critical current density; recovering superconductivity in the nanowire within a short time; and preparing the nanowire to absorb next incident photon.

According to an embodiment herein, a resistive barrier is formed across the width of the superconductor nanowire, and wherein the resistive barrier leads to the production of the measurable voltage pulse.

According to an embodiment herein, the optical fiber is associated with data transmission using light pulses travelling along with a long fiber which is usually made of plastic or glass.

According to an embodiment herein, the metal wires are used for transmission in optical fiber communication as signals travel with fewer damages while constituting a single path for the current.

According to an embodiment herein, a superconducting nanowire single photon detector (SNSPD) comprises a thin film of superconducting material shaped into a meandering nanowire through nanofabrication processes, and wherein the pattern enables the nanowire to cover a wide surface area, and wherein the length of the superconducting nanowire is hundreds of micrometers, and wherein the nanowire is patterned in a compact meander geometry to create a shape, and wherein the nanowire is cooled well below the superconducting critical temperature and biased with a DC current that is close to but less than the superconducting critical current of the nanowire, and wherein the SNSPD is operated at a certain temperature and a constant current below the critical current of the superconductor is applied to the device, and wherein the nanoscale cross section gives the SNSPD an extremely high level of sensitivity upon absorption of a single photon, and wherein SNSPD is a type of near-infrared single-photon detector based on a current-biased superconducting nanowire.

In an embodiment, the present invention outlines four layers for the superconducting single photon detectors. The first layer comprises of the silicon substrate. It acts as a base layer and all other subsequent layers are deposited on silicon. Moreover, silicon as a substrate will be useful for photon amplification using structures such as the Bragg mirrors which will increase the efficiency of the SSPD. The second layer consists of the STO layer as a buffer layer. The buffer layer with STO also provides for a good interface for the YBCO superconducting layer. Moreover, the buffer layer is used for performing the patterning for the required SSPD structure for single photon detection before depositing the YBCO layer. The third layer consists of the superconducting layer YBCO that is responsible for single photon detection. The final layer is a metal layer for making contacts consisting of silver or gold.

According to an embodiment herein, a process for forming ultra-thin films fabricated on Silicon substates is provided. Such processes are greatly affected by lattice mismatch between the thin films and the substrate. In the present invention, a buffer layer (STO/MgO) is sputtered on top of the substrate.

According to an embodiment herein, the buffer layer is used to reduce such lattice mismatch or optimize the strain in the film, thereby improving device performance. The choice and quality of the buffer layer also improves the critical temperature by several Kelvin (up to 10 K), critical current density and lower residual resistivity. Moreover, the buffer layer is suitably chosen to be transparent over a broad wavelength range from the visible to the near infrared so the superconducting stack can be used for a wide variety of applications, from imaging to quantum communications and quantum computing.

According to an embodiment herein, the detector disclosed in the embodiments herein, is a building block for myriad of applications ranging from communication, computing, defense to healthcare.

Communication security is of strategic importance to consumers, enterprises, and governments alike. At present, it is provided by encryption via classical computers which is broken by a quantum computer. Quantum Key Distribution (QKD) is a solution to provide cryptographic key between two parties, resolving the eavesdropping threat leading to secure transmission of data. However, the performance of such systems are limited by the efficiency of single-photon detectors. Currently used single photon detectors are bulky, operate at <4 K and are costly for large scale adoption. The embodiments herein disclose a high temperature superconductor based superconducting single photon detectors which is of low cost, scalable, compact and provides ease of commercial deployment.

According to an embodiment herein, Photonic-based Quantum Computing requires Single photon sources, detectors, and optical systems. It is essential to have extremely sensitive single photon detectors with near unity Quantum Detection Efficiency and Photon Number Resolving capability not common in current available detectors. The detector disclosed in the embodiments herein is used with chip electronics to build an optical quantum computing systems with high quantum detection efficiency.

The detector disclosed in the embodiments herein is used for Time-of-Flight Depth Ranging (LiDAR), Single molecule detection for bio-imaging, Optical time domain reflectometry, Semiconductor circuit inspection, Star light correlation spectroscopy, Diffuse optical tomography, Positron emission tomography and Quantum metrology measurements.

According to one embodiment herein, nanowires are patterned on the buffer layer. The transport properties of the nanowires is obtained/achieved by conventional four-point measurement in a 3He refrigerator reaching a base temperature of 300 mK. The current and voltage probes of the 4-point measurement setup are situated at the far ends of the electrodes connected to the nanowire. Thus, the resistance of the nanowires in series with the resistance of the two wide electrodes is measured. Subsequently, the current-voltage characteristics (IVC) for the nanowire are plotted at 4.2 K. The critical current densities Jc is plotted as a function of the width of the nanowire. The critical current densities ideally approach the depairing current density (predicted by the Ginzburg-Landau (GL) theory) to ensure pristine growth of the superconducting layer.

According to an embodiment herein, the lithography and or etching process comprises the following steps: the first step involves deposition of STO layer on top of the Silicon Substrate. In the next embodiment of the invention, post-deposition lithography is performed on the buffer layer using an electron beam at 20 KV which provides extremely high resolution. It makes use of the highly energetic, tightly focused electron beam, which is scanned over a sample coated with an electron-sensitive resist. The electron beam scans the image according to a pattern defined on a CAD file. The sample is then developed in an appropriate solvent which reveals the structures defined into the resist. This acts as a mould for subsequent pattern transfer techniques such as dry etching or metal lift-off.

According to an embodiment herein, the etching process involves plasma to remove materials deposited on the substrate. Plasma is generated under low pressure by electromagnetic field. High energy ions from the plasma attack the wafer surface and react with it to remove the film. The method involves reactive ion etching (RIE) with fluorine chemistry.

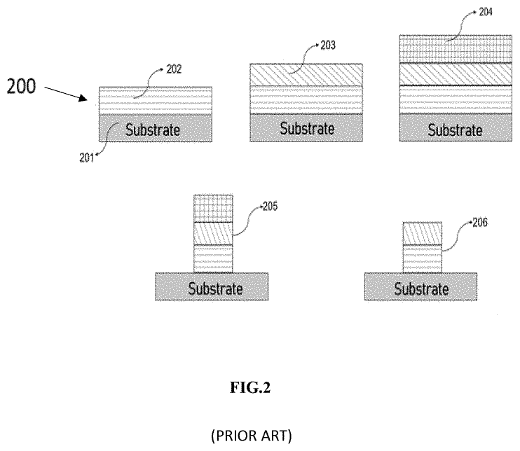

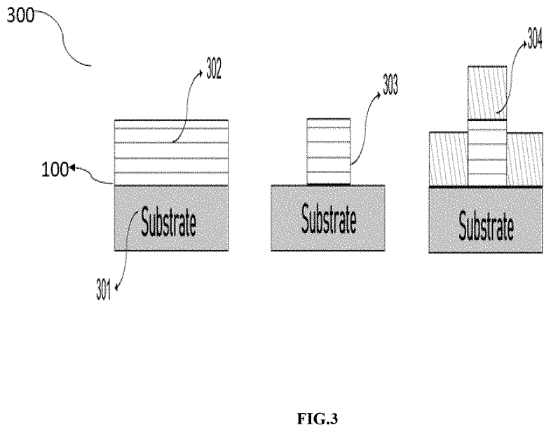

According to an embodiment herein, the basic processes to carry out the deposition of required layers or the layers and the type may change without defeating the essence of the invention. The basic idea being the patterning and subsequent deposition of the superconducting layer as opposed to first deposition of superconducting layer followed by patterning. The idea not only reverses the order for patterning, but it also provides for a cleaner surface for the superconductor deposition, increasing the efficiency of the device. As photon detection happens at the surface of the superconductor, having a cleaner surface would increase the detection efficiency which can be damaged while patterning the superconducting layer as is done in conventional processes. Moreover, the present method also reduces the number of steps for fabricating SSPD as outlined in FIGS. 2, 3, 4 and 5 which is crucial for large scale fabrication and adoption of SSPDs. FIG. 2 and FIG. 3 gives the difference between the conventional method and the proposed method for fabricating SSPDs.

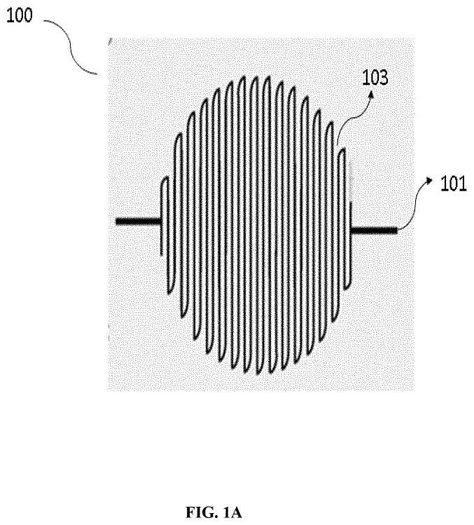

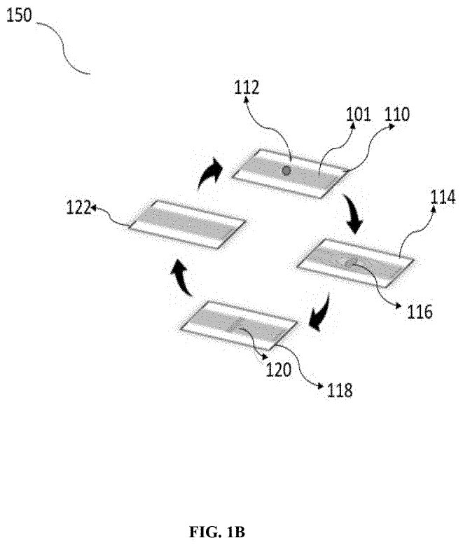

FIG. 1A illustrates a Superconducting Nanowire Single Photon Detector (SNSPD) 100 with superconducting nanowire 101 meandering, in accordance with an embodiment of the present invention. In one embodiment, SNSPD 100 is a type of, and near-infrared single-photon detector based on a current-biased superconducting nanowire. In one embodiment, the superconducting nanowire single photon detector 100 consists of a thin film of superconducting material shaped into a meandering nanowire 101 through nanofabrication processes. This pattern enables the nanowire 101 to cover a wide surface area.

In one embodiment, the SNSPD 100 includes of a thin and narrow superconducting nanowire 101. In one example, the meandered superconducting nanowire 101 has a width 103 of less than or equal to 100 nm. In one embodiment, the length of the superconducting nanowire 101 is typically hundreds of micrometers. In one embodiment, the nanowire 101 is patterned in a compact meander geometry to create a shape. For example, the shape of the meandered nanowire 101 is a square or circular pixel with a maximum detection efficiency. In one embodiment, the nanowire is cooled well below its superconducting critical temperature and biased with a DC current that is close to but less than the superconducting critical current of the nanowire 101. In one embodiment, the nanowire 101 collects the whole output of an optical fiber. In one embodiment, the optical fiber is associated with data transmission using light pulses travelling along with a long fiber which is usually made of plastic or glass. Metal wires are preferred for transmission in optical fiber communication as signals travel with fewer damages while constituting a single path for the current. In one embodiment, the SNSPD 100 is operated at a certain temperature and a constant current below the critical current of the superconductor is applied to the device. In one embodiment, the nanoscale cross section gives the SNSPD 100 an extremely high level of sensitivity upon absorption of just a single photon. In one embodiment, typically, once a single photon is absorbed in the meandering nanowire 101, superconductivity is locally broken. As a result, the current is directed towards the amplification electronics and creates a voltage pulse. After the photon is absorbed, superconductivity recovers in the nanowire 101 within a short time. The process is repeated for multiple photons, with one photon at a time.

According to FIG. 1A, in an exemplary embodiment, the SNSPD 100 consisting of the meandered superconducting nanowire 101 with a width 103 of size 100 nm. In one embodiment, the SNSPD 100 operates below its critical temperature and current-biased close to the superconducting current density. Upon absorption of the individual incident photon, a hot spot on the small width of the nanowire 101 is generated and forces the superconducting current to flow around the nanowire 101 region. In one embodiment, the local current density exceeds the critical current density, a resistive barrier will be formed across the width 103 of the superconductor nanowire 101. In one embodiment of the invention, nanowires are patterned on the buffer layer. The transport properties of the nanowires can be obtained by conventional four-point measurement in a 3He refrigerator reaching a base temperature of 300 mK. The current and voltage probes of the 4-point measurement setup are situated at the far ends of the electrodes connected to the nanowire. Thus, the resistance of the nanowires in series with the resistance of the two wide electrodes is measured. Subsequently, the current-voltage characteristics (IVC) for the nanowire are plotted at 4.2 K. The critical current densities Jc is plotted as a function of the width of the nanowire. The critical current densities should ideally approach the depairing current density (predicted by the Ginzburg-Landau (GL) theory) to ensure pristine growth of the superconducting layer.

FIG. 1B illustrates multiple stages 150 of generation of a voltage pulse 120 across nanowires 101 of the Superconducting Nanowire Single Photon Detector (SNSPD), in accordance with an embodiment of the present invention. The process of generation of the voltage pulse 118 in the SNSPD is distinguished into four stages 150. At 110, a photon 112 is incident on the nanowire 101. In one embodiment, the photon 112 breaks Cooper pairs in the nanowires 101 and reduces the local critical current below that of the bias current. At 114, the photon 112 is absorbed in the nanowire 101 and this results in the formation of a localized non-superconducting region or hotspot 116, with finite electrical resistance. For example, the resistance is typically larger than the 50 Ohm input impedance of the readout amplifier, and hence most of the bias current is shunted to the amplifier. At 118, the local current density exceeds the critical current density, which causes a spike in the resistance of superconducting nanowire from zero to a finite value causes the voltage pulse 120 to be generated across the nanowire 101. In one embodiment, a resistive barrier is formed across the width of the superconductor nanowire 101. The resistive barrier will lead to the production of the measurable voltage pulse 120. For example, the voltage pulse 120 is approximately equal to the bias current multiplied by 50 Ohms. With most of the bias current flowing through the amplifier, the non-superconducting region cools and returns to the superconducting state. At 122, superconductivity recovers in the nanowire 101 within a short time and the nanowire 101 prepares to absorb next incident photon (not shown in the FIG).

FIG. 2 illustrates a plurality of processes in the fabrication of superconducting nanowire single photon detector 200 from the deposited thin films using a conventional method. In one embodiment, the SNSPD 200 includes a substrate 201 and a buffer layer 202. The buffer layer 202 is deposited on the substrate 201 of the SNSPD 200 using a deposition method. For example, deposition of any buffer layer 202 on the substrate 201 is the process of creating and depositing thin film coatings onto the substrate 201. The coatings is made of many different materials, from metals to oxides to compounds. In one embodiment, after deposition of the buffer layer 202 on the substrate 201, the next stage includes deposition of a superconducting thin film 203 on the buffer layer 202 using any suitable deposition technique.

The next stage includes encapsulation of the superconducting thin film 203. In an embodiment, the encapsulation is achieved by depositing a layer of gold 204. i.e., the superconducting thin film 203 is surrounded by the gold (Au) layer 204. Further, the multiple deposited layers such as the buffer layer 202, the superconducting film 203 encapsulated with the Au layer 204 is patterned into nanostrips 205. In one embodiment, the Au layer 204 is added to protect the superconducting thin film 203 from any damages during the process of patterning. In one embodiment. Furthermore, at the final stage, the Au encapsulation layer 204 is removed from the top of the superconducting film 203 to form a superconducting nanostrip 206. In one embodiment, the Au encapsulation layer 204 is removed from the top of the superconducting film 203 using an etching process prior to the photo response measurements. As per the convention method described in FIG. 2, the etching process potentially affects the quality of the superconducting thin film 203.

FIG. 3 illustrates a plurality of process steps (300) involved in the fabrication of superconducting nanowires single photon detector 100 according to an embodiment of the present invention. As per FIG. 3, SNSPD 100 includes a substrate 301 and a buffer layer 302, wherein the buffer layer 302 is deposited on the substrate 301. For example, the substrate 301 is a base made of one of Silicon or Magnesium Oxide (MgO) and the buffer layer 302 is made of one of Strontium Titanate (STO). For example, size of the buffer layer 302 less than 100 nm. In one embodiment, the buffer layer 302 is deposited on the substrate 301 through Pulsed Laser Deposition (PLD) technique. The pulsed laser deposition technique is a physical vapor deposition (PVD) technique where a high-power pulsed laser beam is focused inside a vacuum chamber to strike the buffer layer 302. The material of the buffer layer 302 is vaporized (in a plasma plume) and the material is deposited as a thin film on the substrate 301.

According to FIG. 3, the next step in which, the buffer layer 302 is designed into a desired pattern 303. For example, according to FIG. 3, to obtain the desired pattern 303, at least one of lithography and/or etching processes is used in the SNSPD 100. In one embodiment, lithography is defined as a method of printing from a stone or a metal plate (structure) with a smooth surface, wherein the desired design is drawn onto a flat stone (or prepared metal plate) and affixed by means of a chemical reaction. The process of lithography involves deposition of STO layer on top of the Silicon Substrate. In the next embodiment of the invention, post-deposition lithography is performed on the buffer layer using an electron beam at 20 KV which provides extremely high resolution. It makes use of the highly energetic, tightly focused electron beam, which is scanned over a sample coated with an electron-sensitive resist. The electron beam scans the image according to a pattern defined on a CAD file. The sample is then developed in an appropriate solvent which reveals the structures defined into the resist. This acts as a mould for subsequent pattern transfer techniques such as dry etching or metal lift-off. Once the design is complete, the stone or structure is ready to be etched. In etching, a strong acid or mordant is used to cut into the unprotected parts of the metal plate/flat stone to create the desired pattern 303. The etching process involves plasma to remove materials deposited on the substrate. Plasma is generated under low pressure by electromagnetic field. High energy ions from the plasma attack the wafer surface and react with it to remove the film. The invention involves reactive ion etching (RIE) with fluorine chemistry. Further, in the last stage, a superconducting material film 304 is uniformly and non-conformally deposited on the desired pattern 303. In one embodiment, a lattice matching with the buffer layer 302 and the lattice mismatching with the substrate 301 allows the deposition of continuous and high quality superconducting thin film 304 on the desired pattern 303.

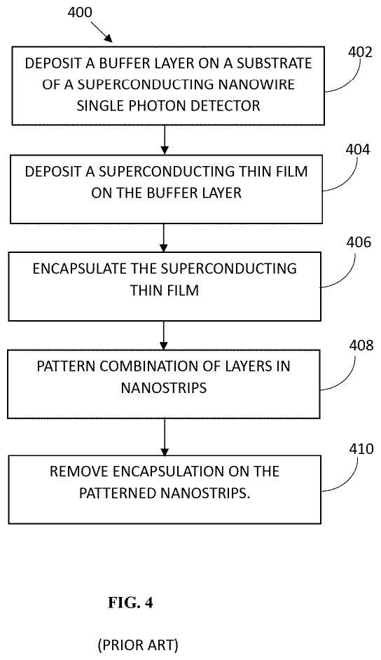

FIG. 4 illustrates a flow chart explaining a method 400 of fabricating superconducting nanowire single photon detector, in accordance with a prior art. At 402, a buffer layer is deposited on the substrate of the SNSPD using a deposition method. At 404, a superconducting thin film is deposited on the buffer layer. The deposition of the superconducting thin film is carried out using any suitable deposition technique. At 406, superconducting thin film is encapsulated. In one embodiment, the encapsulation is achieved by depositing a layer of gold where the superconducting thin film is surrounded by the gold (Au) layer. At 408, the multiple layers such as the buffer layers is deposited, and the superconducting film encapsulated with the Au layer is patterned into nanostrips. At 410, the encapsulation layer on the patterned nanostrips is removed from the top of the superconducting film to form a superconducting nanostrip.

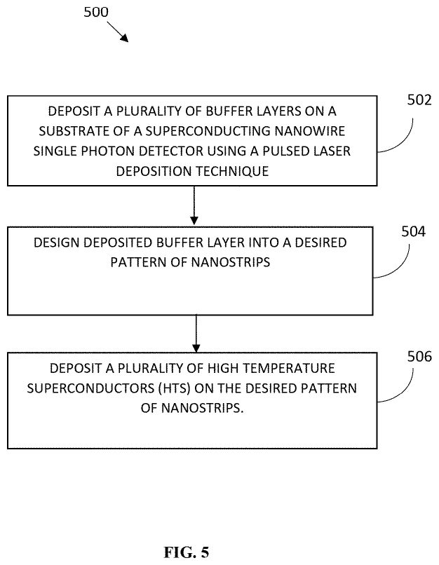

FIG. 5 illustrates a flow chart explaining a method 500 of fabricating superconducting nanowire single photon detector, in accordance with an embodiment of the present invention. At step 502, a plurality of buffer layers is deposited on a substrate of a superconducting nanowire single photon detector using a pulsed laser deposition technique. At step 504, the deposited buffer layer is designed into a desired pattern of nanostrips. At step 506, a plurality of High Temperature Superconductors (HTS) is deposited on the desired pattern of nanostrips. In one embodiment, the HTS has a transition temperature (T_{c}) higher than the temperature of liquid nitrogen. In one embodiment, the HTS fabricates an array of nanowires on the substrate of SNSPD. For example, the T_{c} of the HTS is greater than 77K.

In an embodiment, the basic processes to carry out the deposition of required layers or the layers and the type may change without defeating the essence of the invention. The basic idea being the patterning and subsequent deposition of the superconducting layer as opposed to first deposition of superconducting layer followed by patterning. The idea not only reverses the order for patterning, but it also provides a cleaner surface for the superconductor deposition, increasing the efficiency of the device. As photon detection happens at the surface of the superconductor, having a cleaner surface would increase the detection efficiency which can be damaged while patterning the superconducting layer as is done in conventional processes. Moreover, the present method also reduces the number of steps for fabricating SSPD as outlined in FIGS. 3 and 5 which is crucial for large scale fabrication and adoption of SSPDs.

The embodiments of the present invention provide a method and a system for fabricating superconducting nanowire single photon detector. The described fabrication method preserves the quality of the superconducting material and thereby solve multiple problems related to the fabrication process. The fabrication process allows a high-quality film to be deposited and allows development of a cost-effective single photon detector. The fabrication of SNSPD using the described method can be used for various different substrates, buffer layers and HTS materials and hence provides a flexible solution. Moreover, the fabrication is applicable to other such processes involving superconducting materials. Also, the described method eliminates the step of gold encapsulation, wherein currently gold encapsulation results in deterioration of the superconducting properties in the fabrication. Typically, processes for forming ultra-thin films fabricated on Silicon substates, are greatly affected by lattice mismatch between the thin films and the substrate. In the present technology, a buffer layer (STO/MgO) is sputtered on top of the substrate Such deterioration of the superconducting properties can be eliminated completely and hence the fabrication process is made much simpler. The buffer layer is used to reduce such lattice mismatch or optimize the strain in the film, thereby improving device performance. The choice and quality of the buffer layer also improves the critical temperature by several Kelvin (up to 10 K), critical current density and lower residual resistivity. Moreover, the buffer layer is suitably chosen to be transparent over a broad wavelength range from the visible to the near infrared so the superconducting stack can be used for a wide variety of applications, from imaging to quantum communications and quantum computing.

The present invention is a building block for myriad of applications ranging from communication, computing, defense to healthcare. Communication security is of strategic importance to consumers, enterprises, and governments alike. At present, it is provided by encryption via classical computers which could be broken by a quantum computer. Quantum Key Distribution (QKD) is a solution to provide cryptographic key between two parties, resolving the eavesdropping threat leading to secure transmission of data. However, the performance of such systems is limited by the efficiency of single-photon detectors. Currently used single photon detectors are bulky, operate at <4 K and are costly for large scale adoption. The high temperature superconductor based superconducting single photon detectors disclosed in the embodiments herein, is of low cost, scalable, compact and provides ease of commercial deployment. Photonic-based Quantum Computing requires Single photon sources, detectors, and optical systems. It is essential to have extremely sensitive single photon detectors with near unity Quantum Detection Efficiency and Photon Number Resolving capability not common in current available detectors. The current invention can be used with chip electronics to build an optical quantum computing systems with high quantum detection efficiency. The present invention can be used for Time-of-Flight Depth Ranging (LiDAR), Single molecule detection for bio-imaging, Optical time domain reflectometry, Semiconductor circuit inspection, Star light correlation spectroscopy, Diffuse optical tomouraphy, Positron emission tomography and Quantum metrology measurements.

The foregoing description of the specific embodiments will so fully reveal the general nature of the embodiments herein that others can, by applying current knowledge, readily modify and/or adapt for various applications such as specific embodiments without departing from the generic concept, and, therefore, such adaptations and modifications should and are intended to be comprehended within the meaning and range of equivalents of the disclosed embodiments.

It is to be understood that the phraseology or terminology employed herein is for the purpose of description and not of limitation. Therefore, while the embodiments herein have been described in terms of preferred embodiments, those skilled in the art will recognize that the embodiments herein can be practiced with modifications. However, all such modifications are deemed to be within the scope of the claims.

What is claimed is:

1. A method of fabricating superconducting nanowire single photon detector (SNSPD), the method comprising:
depositing a plurality of buffer layers on a substrate of a superconducting nanowire single photon detector using a pulsed laser deposition technique;
designing deposited buffer layer into a desired pattern of nanostrips; and
depositing a plurality of high temperature superconductor (HTS) on the desired pattern of nanostrips.

2. The method of claim 1, wherein a lattice matching with the buffer layer and the lattice mismatching with the substrate allows the deposition of continuous and high quality superconducting thin film on the desired pattern.

3. The method of claim 1, wherein the pulsed laser deposition technique (PLD) is a physical vapor deposition (PVD) technique, and wherein the pulsed laser deposition technique comprises:
focusing a high-power pulsed laser beam inside a vacuum chamber to strike the plurality of buffer layers;
vaporizing the material of the plurality of buffer layers in a plasma plume; and
depositing the material as a thin film on the substrate of superconducting nanowire single photon detector.

4. The method of claim 1, wherein at least one of lithography or etching processes is used in the SNSPD to obtain the desired pattern.

5. The method of claim 4, wherein the lithography process comprises:
depositing a plurality of buffer layer on top of the silicon substrate;
performing a post-deposition lithography on the buffer layer using an electron beam at 20 kilo volts (KV) or more for providing high resolution;
scanning the image according to a pattern defined on a computer aided design (CAD) file using the electron beam; and
developing the sample in an appropriate solvent for revealing the structures defined into the resist.

6. The method of claim 5, wherein the etching process comprises:
generating the plasma under low pressure by electromagnetic field;
attacking the wafer surface using high energy ions from the plasma; and
removing materials deposited on the substrate using a plasma.

7. The method of claim 1, wherein a superconducting material film is uniformly and non-conformally deposited on the desired pattern.

8. A method of working of a superconducting nanowire single photon detector (SNSPD), the method comprising:
patterning the superconducting nanowire in a compact meander geometry to create a shape;
cooling the superconducting nanowire, below a superconducting critical temperature and biasing with a direct current close to and less than the superconducting critical current of the nanowire;
collecting the whole output of an optical fiber using the superconducting nanowire;
operating the SNSPD at a certain temperature;
applying a constant current below the critical current of the superconductor to the device;
giving the SNSPD a high level of sensitivity upon absorption of just a single photon using the nanoscale cross section;
absorbing a single photon in the meandering nanowire, wherein the superconductivity is locally broken;
directing the current towards the amplification electronics;
creating a voltage pulse; and
recovering the superconductivity in the nanowire within a short time after the photon is absorbed.

9. The method of claim 8, further comprising repeating the steps for a plurality of photons, with one photon at a time.

10. The method of claim 8, wherein creating the voltage pulse comprises:
incidenting a photon on the nanowire;
breaking a plurality of Cooper pairs in the nanowires using the plurality of photons;
absorbing the photon in the nanowire;
resulting in the formation of a localized non-superconducting region or hotspot, with finite electrical resistance;
causing a spike in the resistance of superconducting nanowire from zero to a finite value causes the voltage pulse to be generated across the nanowire by exceeding the local current density from the critical current density;
recovering superconductivity in the nanowire within a short time; and
preparing the nanowire to absorb next incident photon.

11. The method of claim 10, wherein a resistive barrier is formed across the width of the superconductor nanowire.

12. The method of claim 11, wherein the resistive barrier will lead to the production of the measurable voltage pulse.

13. The method of claim 8, wherein the optical fiber is associated with data transmission using light pulses travelling along with a long fiber which is usually made of plastic or glass.

14. The method of claim 13, wherein the metal wires are used for transmission in optical fiber communication as signals travel with fewer damages while constituting a single path for the current.

15. A superconducting nanowire single photon detector (SNSPD) comprising:
a thin film of superconducting material shaped into a meandering nanowire through nanofabrication processes, wherein the pattern enables the nanowire to cover a wide surface area, and wherein the length of the superconducting nanowire is hundreds of micrometers, and wherein the nanowire is patterned in a compact meander geometry to create a shape, and wherein the nanowire is cooled well below the superconducting critical temperature and biased with a DC current that is close to but less than the superconducting critical current of the nanowire, and wherein the SNSPD is operated at a certain temperature and a constant current below the critical current of the superconductor is applied to the device, and wherein the nanoscale cross section gives the SNSPD an extremely high level of sensitivity upon absorption of a single photon, and wherein SNSPD is a type of near-infrared single-photon detector based on a current-biased superconducting nanowire.
